(19) United States
(12) Patent Application Publication
(10) Pub. No.: US 2019/0122885 A1
(43) Pub. Date: Apr. 25, 2019

(54) GROUP III SEMICONDUCTOR EPITAXY FORMED ON SILICON VIA SINGLE CRYSTAL REN AND REO BUFFER LAYERS

(71) Applicants: Rytis Dargis, Oak Ridge, NC (US); Andrew Clark, Mountain View, CA (US); Michael Lebby, San Francisco, CA (US); Rodney Pelzel, Bethlehem, PA (US); IQE plc, St. Mellons, Cardiff (GB)

(72) Inventors: Rytis Dargis, Oak Ridge, NC (US); Andrew Clark, Mountain View, CA (US); Michael Lebby, San Francisco, CA (US); Rodney Pelzel, Emmaus, PA (US)

(21) Appl. No.: 16/093,521

(22) PCT Filed: Apr. 10, 2017
(86) PCT No.: PCT/US2017/026856

§ 371 Date: Oct. 12, 2018

Related U.S. Application Data
(60) Provisional application No. 62/322,141, filed on Apr. 13, 2016.

(51) Int. Cl. H01L 21/02; H01L 29/04

(52) U.S. Cl. CPC H01L 21/02483; H01L 29/045; H01L 21/02631; H01L 21/0262; H01L 21/02609; H01L 21/02433; H01L 21/02516; H01L 21/02538; H01L 21/0254; H01L 21/02381

(57) ABSTRACT

Layer structures are described for the formation of Group III-V semiconductor material over Si<110> and Si<100>. Various buffer layers and interfaces reduce the lattice strain between the Group III-V semiconductor material and the Si<110> or Si<100> layers, allowing for the epitaxial formation of high quality Group III-V semiconductor material.

### CROSS REFERENCE TO RELATED APPLICATIONS

This application claims the benefit of U.S. Provisional Patent Application No. 62/322,141, filed on Apr. 13, 2016, the entire contents of which are hereby incorporated by reference.

### BACKGROUND

Direct epitaxial growth of Group III-V semiconductors on Si<100> and Si<110> wafers is, in many cases, impossible due to lattice, thermal expansion and other mismatches between the semiconductor lattice and the silicon wafer. Epitaxial rare earth oxides (REO) may be used as intermediate layers between silicon wafers and semiconductor layers to enable growth of Group III semiconductors, however REO layers may have their own lattice mismatch problems. For REOs with cubic-bixbyite lattice structures, polymorphisms of the oxides, as well as different oxidation states may present a variety of issues that result from lattice mismatch between the Si<110> and Si<100> orientations of the wafers and the REOs, and which ultimately limit the ability to grow Group III semiconductors of the desired quality and thickness.

### SUMMARY

Layer structures for forming Group III-V semiconductors on Si<110> and Si<100> are described herein. A layer structure includes a first layer of silicon having a <100> orientation. A rare earth oxide layer is over the first layer. A Group III containing layer is over the rare earth oxide layer. The Group III containing layer has either a <100> orientation or a <0001> orientation. The Rare earth oxide layer and the Group III containing layer are epitaxially formed.

The layer structure may have an interface between layers that is an abrupt rotation in crystal orientation between a <100> orientation and a <110> orientation. This interface may be between the first layer and an adjacent layer. The layer structure may have an interface between a rare earth containing layer and an a first adjacent layer that has a region with a thickness greater than 100 nm. The region has an alloy of a first element of the rare earth layer and a second element of the adjacent layer. The first adjacent layer may be a Group III-V containing layer, and the first element may be a Group V element. The first adjacent layer may be a crystalline rare earth oxide layer and the first element may be a rare earth element.

The rare earth oxide layer may be a crystalline rare earth oxide, and the Group III containing layer may be a Group III-V containing layer having a <100> orientation. The layer structure may include a nitride layer having a <100> orientation between the first layer and the crystalline rare earth oxide layer. The layer structure may have a rare earth and Group V (RE-V) containing layer between the crystalline rare earth oxide layer and the Group III-V containing layer.

The layer structure may include a hexagonal rare earth oxide layer over the first layer and having a <0001> orientation. The rare earth oxide layer may be a cubic rare earth oxide layer, and the Group III containing layer may be a nitride and Group III layer. The hexagonal rare earth oxide layer may be epitaxially formed. The layer structure may also include a cubic rare earth nitride containing layer over the hexagonal rare earth oxide layer. An interface between the first layer and the cubic rare earth oxide layer may be a single rotation in crystal orientation between a <100> orientation and a <110> orientation. The layer structure may also include a rare earth silicide (RESi) layer having a <0001> orientation. The RESi layer may be adjacent to the cubic rare earth oxide layer, and an interface between the RESi layer and the cubic rare earth oxide layer may be a single rotation in crystal orientation between a <110> orientation and a <0001> orientation. An interface between the hexagonal rare earth oxide layer and the cubic rare earth oxide layer may be a single rotation in crystal orientation between a <110> orientation and a <0001> orientation.

A layer structure has a first layer of silicon having a <110> orientation. A hexagonal rare earth oxide layer is over the first layer and has a <0001> orientation. A III-nitride containing layer is over the hexagonal rare earth oxide layer. The hexagonal rare earth oxide layer and the III-nitride containing layer are epitaxially formed, and the III-nitride containing layer has a <0001> orientation. The layer structure may include a cubic rare earth nitride (RE-nitride) containing layer having a <111> orientation over the hexagonal rare earth oxide layer.

### BRIEF DESCRIPTION OF THE DRAWINGS

Further features of the subject matter of this disclosure, its nature and various advantages, will be apparent upon consideration of the following detailed description, taken in conjunction with the accompanying drawings, in which like reference characters refer to like parts throughout, and in which:

FIG. 1 is a general layer diagram of a prior art structure including III-V semiconductor layer having a <111> orientation on Si<111> via a REO buffer layer, according to an illustrative implementation;

FIG. 2 is a layer diagram of a very restricted prior art method of growing REO having a <100> orientation on Si<100>, according to an illustrative implementation;

FIG. 3 is a layer diagram of a general structure with a Group III semiconductor layer on Si<100> via a REO buffer layer, according to an illustrative implementation;

FIG. 4 is a layer diagram of a structure with a Group III-V semiconductor layer having a <100> orientation on Si<100> via a REO buffer layer, according to an illustrative implementation;

FIG. 5 is a layer diagram of a structure with a Group III-V semiconductor layer having a <100> orientation on Si<100> via a cubic REO layer and rare earth and Group V alloy (RE-V) containing layer, according to an illustrative implementation;

FIG. 6 is a layer diagram of a structure with a Group III-V semiconductor layer having a <100> orientation on Si<100> via a cubic rare earth nitride (REN) layer and a cubic REO layer, according to an illustrative implementation;

FIG. 7 is a layer diagram of a structure with a Group III nitride (III-N) semiconductor layer on Si<100> via a cubic REO layer and a hexagonal REO layer, according to an illustrative implementation;

FIG. 8 is a layer diagram of a structure with a III-N semiconductor layer having a <0001> orientation on Si<100> via a cubic REO layer, a hexagonal REO layer and a cubic REN layer, according to an illustrative implementation;

FIG. 9 is a layer diagram of a structure with a III-N semiconductor layer having a <0001> orientation on Si<100> via a cubic REO layer, a hexagonal rare earth silicide (RESi) layer, a hexagonal REO layer and a cubic REN layer, according to an illustrative implementation;

FIG. 10 is a layer diagram of a structure with a III-N semiconductor layer having a <0001> orientation on Si<110> via a hexagonal REO layer and a cubic REN layer, according to an illustrative implementation;

FIG. 11 is a layer diagram of a chemical barrier between layers formed in subsequent processing, according to an illustrative implementation; and

FIG. 12 is a schematic diagram of crystallographic alignment for hexagonal material on cubic material, according to an illustrative implementation.

### DETAILED DESCRIPTION

In the following description, numerous details are set forth for the purpose of explanation. However, one of ordinary skill in the art will realize that the embodiments described herein may be practiced without the use of these specific details. In other instances, well-known structures and devices are shown in block diagram form so that the description will not be obscured with unnecessary detail.

Integration of electronics and photonic devices is a major driver of reducing chip size and costs in the semiconductor industry. Since most electronic and photonic devices are formed on either Si<100> or Si<110>, because of higher charge carrier mobility in these crystal orientations, being able to grow photonic and electronic device heterostructures on Si<100> or Si<110> is advantageous. However, Group III semiconductor layers are almost impossible to grow directly on Si<100> or Si<110>, and thus buffer layers that relax lattice strain and improve thermal expansion differences between the Group III semiconductor layer and the Si<100> or Si<110> layer are used, opening up the possibility of epitaxy of Group III semiconductor layers on commercially crucial Si<100> and Si<110>.

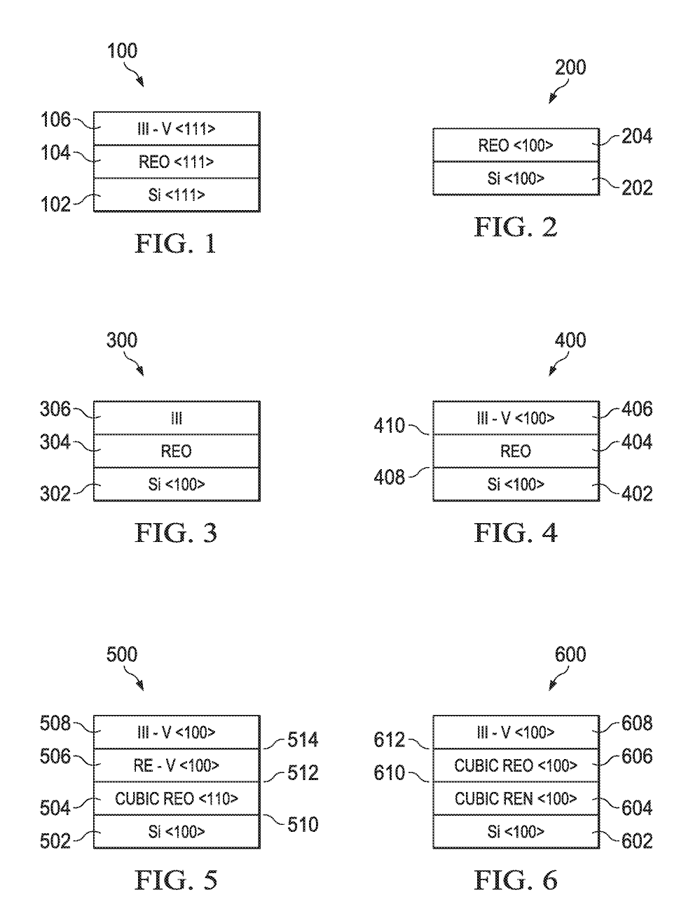

Many proposals have been published that include the use of rare earth oxides for a buffer to grow semiconductor material on crystalline silicon wafers with a <111> orientation. For example, a U.S. Pat. No. 7,384,481, entitled “Method of Forming a Rare-Earth Dielectric Layer”, Patented Jun. 10, 2008, the entirety of which is incorporated by reference herein, describes growth of compound semiconductors (III-Vs) on a Si substrate via a rare-earth oxide (REO) buffer layer. Also, a possibility to grow acceptable quality indium phosphide (InP) on epitaxial Gd₂O₃ was demonstrated by some groups despite a substantial lattice mismatch between the REO and the compound semiconductor (See G. Saint-Girons et al., Applied Physics Letters 91, 241912 (2007), the entirety of which is incorporated by reference herein). The relatively large lattice mismatch between the REO and the compound semiconductor is advantageous in this instance because it leads to low critical layer thickness of the compound semiconductor (in a range of monolayers) and relaxation of the lattice mismatch induced stress in the semiconductor crystal structure through dislocation networks that are confined at the very interface with the REO. A basic structure of this type is illustrated in FIG. 1.

Some authors published results of epitaxy of REO<100> orientation on Si<100>. This process makes possible the direct growth of a <100> oriented semiconductor layer on REO<100>, as illustrated in FIG. 2. For example, Gd₂O₃ and Dy₂O₃ were formed on Si<100> at specific process parameters using chemical vapor deposition (CVD) technique (See A. P. Milanov et al., Chem. Mater. 21, 5443 (2009), the entirety of which is incorporated by reference herein). However the oxide growth was obtained with very specific precursors of the rare-earth materials and improvement of the morphology of the layers requires further optimization of the process. Also, the possibility of molecular beam epitaxy (MBE) growth of Gd₂O₃ <100> on Si<100> was described by W. Sitaputra and R. Tsu (App. Phys. Lett 101, 222903 (2012), the entirety of which is incorporated by reference herein). Low substrate temperature influences the growth kinetics and prevents formation of <110> and <111> oriented layers. Repeatability might be complicated using this method since kinetic control of the process has very narrow process parameter windows.

In RF and other applications, polar orientation (<0001>) of Group III nitride (III-N) semiconductor layers is a preferred orientation because of the spontaneous polarization fields that occur along the <0001> axis. While growing polar III-N semiconductors on Si<111> is the least complicated silicon orientation, Si<110> and Si<100> wafers are far more prevalent due to their use in CMOS electronics. However, epitaxy of wurtzite (<0001>) crystal structure of polar III-N on Si<110> and Si<100> has proved difficult due to differences in surface crystal symmetry (rectangular vs. hexagonal). While growth of polar <0001> gallium nitride (GaN) on Si<110> has been described (D Marti et al., Applied Physics Express 4, 064105 (2011), the entirety of which is incorporated by reference herein) the addition of dielectric buffers as described in the present disclosure would enable gallium nitride (GaN) and other III-N semiconductors to better integrate with mainstream silicon based CMOS electronic and other technologies using Si<100> and Si<110>.

There is thus a need for wafer structures that allow for growth of Group III semiconductors (both Group III-V and polar III-N) on industry standard silicon wafers in Si<100> and Si<110> orientations.

The present disclosure provides new and improved growth of III-V semiconductor material on both Si<100>, producing structures with Group III semiconductor layers in <100> orientation and <0001> orientation on Si<100> and Si<110> respectively.

FIG. 1 is a general layer diagram of a prior art structure including Group III-V semiconductor layer having a <111> orientation on Si<111> via a REO buffer layer, according to an illustrative implementation. The layer structure 100 as shown in FIG. 1 is a previous but limited solution to producing a Group III semiconductor layer on silicon via a REO buffer layer. As shown in FIG. 1, the Group III-V semiconductor layer 106 is in a <111> orientation, while the Si bottom layer 102 is in a <111> orientation and REO buffer layer 104 is in a <111> orientation. The relatively large lattice mismatch between the REO buffer layer 104 and the Group III-V semiconductor layer 106 is, in this case, advantageous because it leads to low critical layer thickness of the Group III-V semiconductor layer 106 and relaxation of the lattice mismatch induced stress in the Group III-V semiconductor layer 106 through dislocation networks that are confined at the very interface with the REO buffer layer 104. While the layer structure 100 allows for a Group III semiconductor layer to be formed on silicon via a REO buffer layer, this layer structure 100 is dependent on the Si layer being in an <111> orientation.

From the perspective of integration with MOSFET electronics and other industry standard silicon substrates, the layer structure 100 with Si having a <111> orientation is not as useful since MOSFET electronics are typically formed on Si having <100> or <110> orientations.

FIG. 2 is a layer diagram of a very restricted prior art method of growing REO having a <100> orientation on Si<100>, according to an illustrative implementation. The layer structure 200 shown in FIG. 2 has REO layer having a <100> orientation over a Si layer having a <100> orientation. REO layer 204 may be Gd₂O₃ or Dy₂O₃ formed using specific process parameters using chemical vapor deposition (CVD). Structure 200 was only possible with very specific precursors of the rare-earth materials, and result in less desirable morphology of the REO layer 204, limiting the thickness of any subsequent semiconductor layers formed over the REO layer 204. Improvements to structure 200 would allow for relaxed process parameters and produce more consistent REO crystal structure. Additionally, growth of REO layers using molecular beam epitaxy (MBE) is preferred over CVD, since REO formed by MBE results in better crystallinity and may enable additional layers to be constructed over the REO layer. The layer structure 200 has only been shown using CVD deposition of the REO layer 204.

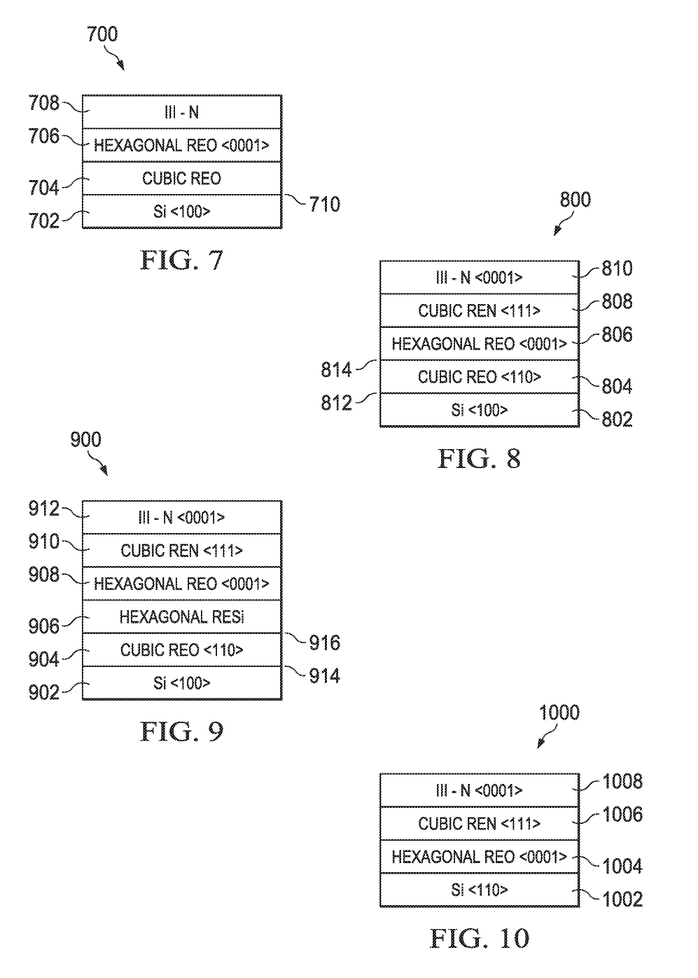

FIG. 3 is a layer diagram of a general structure with a Group III semiconductor layer on Si<100> via a REO buffer layer, according to an illustrative implementation. Layer structure 300 includes a Group III semiconductor layer 306 over a REO buffer layer 304. The Group III semiconductor layer 306 and REO buffer layer 304 are both over a silicon layer 302 having a <100> orientation. The Group III semiconductor layer 306 may be a wurtzite crystal structure having a <100> orientation (as described in further detail with reference to FIG. 4-6), or a polar crystal structure having a <0001> orientation (as described in further detail with reference to FIG. 7-10). There may be additional layers between silicon layer 302 and REO layer 304 (not shown). There may also be additional layers between REO layer 304 and Group III semiconductor layer 306 (not shown). The silicon layer 302 may be formed over additional layers (not shown).

As shown in FIG. 3, the REO buffer layer 304 is between the Group III semiconductor layer 306 and the silicon layer 302. REO buffer layer 304 relaxes lattice strain between the Si <100> layer 302 and the Group III semiconductor layer 306, which would otherwise cause formation of extended defects into the Group III semiconductor layer 306 and the formation of anti-phase boundaries that limit charge carrier mobility. The crystal lattice spacing of the REO layer may be close to that of the Si <100> layer to reduce strain, and various REOs have a crystal lattice spacing that can be substantially matched to silicon with very little strain at the interface between the REO buffer layer 304 and the silicon layer 302. For example, Gd₂O₃ has a crystal lattice spacing a of 10.81 Å, Er₂O₃ has a crystal lattice spacing a of 10.55 Å, Nd₂O has a crystal lattice spacing (a) of 11.08 Å, and silicon has a double spacing 2a of 10.86 Å. Also, two or more rare earth materials can be mixed in the REO buffer layer 304 to bring the crystal spacing to a desired level and produce tensile or compressive strain as desired to offset the strain in layers formed above it, for example the Group III semiconductor layer 306. Further, the crystal lattice spacing of the REO buffer layer 304 can be varied by varying the composition of the constituents. The REO buffer layer 304 thus acts as a compliant substrate for the growth of the Group III semiconductor layer, allowing for the formation of Group III semiconductor layer 306 with reduced lattice strain.

The REO buffer layer 304 may be in a cubic crystal orientation. If the REO buffer layer 304 is in a <110> orientation, the interface between the silicon layer 302 and the REO buffer layer 304 may be an abrupt rotation in crystal orientation between silicon in a <100> orientation and the <110> crystal orientation of the REO buffer layer 304. This abrupt rotation may produce an interface between the REO buffer layer 304 and the silicon layer 302 that is an atomically sharp interface between the <100> and <110> orientations. The interface may thus be less than 1 nm. A method of growing a single crystal stress managing layer on a silicon substrate with a <100> surface (such as the silicon layer 302 as shown in FIG. 3) and a REO layer in a <110> orientation (such as the REO layer 304 as shown in FIG. 3) is described in U.S. Pat. No. 8,846,504 B1, entitled “GaN on SI(100) Substrate Using Epi-Twist,” issued Sep. 30, 2014, the entire contents of which are incorporated by reference herein. Structures and methods employing rare-earth compounds to enable heteropitaxy of different semiconductor materials of different orientations are described in U.S. Pat. No. 8,106,381 B2, entitled “Semiconductor Structures with Rare-Earths,” issued Jan. 31, 2012, the entire contents of which are incorporated by reference herein.

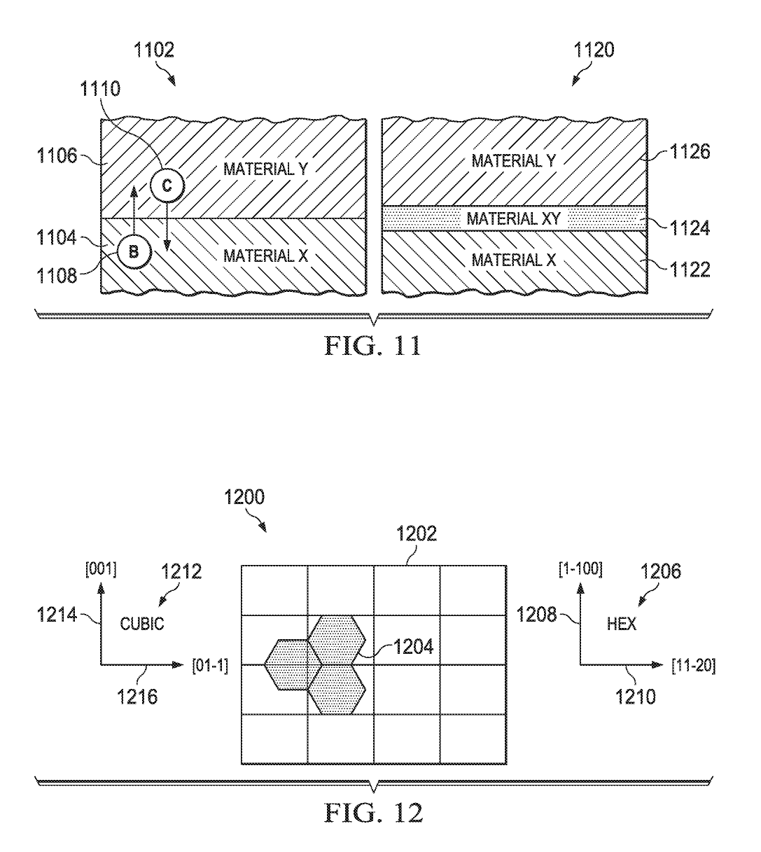

The interface between the REO buffer layer 304 and the Group III semiconductor layer 306 may be a graded transition area that minimizes lattice mismatch and reduces dislocation density. This interface is described in further detail with reference to FIG. 11.

FIG. 4 is a layer diagram of a structure with a Group III-V semiconductor layer having a <100> orientation on Si<100> via a REO buffer layer, according to an illustrative implementation. Layer structure 400 as shown in FIG. 4 has a silicon layer 402 having a <100> orientation. The REO buffer layer 404 is shown formed over the silicon layer 402. The Group III-V semiconductor layer 406 having a <100> orientation is shown formed over both the silicon layer 402 and the REO buffer layer 404. The silicon layer 402 may be the silicon layer 302, the REO buffer layer 404 may be the REO buffer layer 304, and the Group III-V semiconductor layer 406 may be the Group III semiconductor layer 306, all with reference the FIG. 3. There may be additional layers between silicon layer 302 and REO layer 304 (not shown). There may also be additional layers between REO layer 304 and Group III semiconductor layer 306 (not shown). The silicon layer 302 may be formed over additional layers (not shown).

The Group III-V semiconductor layer 406 is shown in FIG. 4 having a <100> orientation. The REO buffer layer may be a cubic bixbyite crystal structure, having a <110> or <100> crystal orientation. The Group III-V semiconductor layer 406 is in a cubic crystal orientation <100>.

If REO buffer layer is in a <110> orientation, an abrupt rotation between the silicon layer 402 at interface 408, and a second abrupt rotation between REO buffer layer 404 and the Group III-V semiconductor layer 406 at interface 410 will allow for the growth of Group III-V semiconductor layer on silicon having a <100> orientation. The abrupt rotations at both interfaces 408 and 410 utilize the tendency of Group III-V semiconductor layers such as 406 to produce <100> crystal orientations when formed on the <110> orientation of the REO buffer layer 404, while the REO buffer layer 404 energetically prefers to produce a <110> orientation when formed on silicon having a <100> orientation. The resulting layer structure 400 thus allows for the suppression of antiphase domains in the Group III-V layer 406 that would otherwise be formed by attempting to epitaxially grow directly on the silicon layer 402. The layer structure 400 thus allows for the formation of high quality Group III-V semiconductor material at layer 406 on Si <100> while reducing lattice stress through both rotational interfaces 408 and 410.

It is also possible to achieve reduction in lattice strain in the layer structure 400 by including a graded transition between the Group III-V semiconductor layer 406 and the REO buffer layer 404. Thus the interface 410 may include a mixture of compounds in both the REO buffer layer 404 and the Group III-V semiconductor layer 406. This interface is described in further detail with reference to FIG. 11.

FIG. 5 is a layer diagram of a structure with a Group III-V semiconductor layer having a <100> orientation on Si<100> via a cubic REO layer and rare earth and Group V alloy (RE-V) containing layer, according to an illustrative implementation. As shown in FIG. 5, a cubic REO layer 504 having a <110> orientation is over a silicon layer 502 having a <100> orientation. The RE-V containing layer 506 having a <100> orientation is over both the Cubic REO layer 504 and the silicon layer 502. A Group III-V semiconductor layer 508 having a <100> orientation is over the RE-V containing layer 506, the cubic REO layer 504 and the silicon layer 502. The silicon layer 502 may be the silicon layer 302, the cubic REO layer 504 may be the REO buffer layer 304, and the Group III-V semiconductor layer 508 may be the Group III semiconductor layer 306, all with reference the FIG. 3. There may be additional layers between silicon layer 502 and cubic REO layer 504 (not shown). There may be additional layers between cubic REO layer 504 and RE-V containing layer 506. There may also be additional layers between RE-V containing layer 506 and Group III-V semiconductor layer 508 (not shown). The silicon layer 502 may be formed over additional layers (not shown).

The layer structure 500 shows another combination of layers that reduces lattice strain between a Group III semiconductor layer and silicon having a <100> orientation, allowing for the growth of high quality Group III semiconductor layers on Si<100>. Layer structure 500 has an interface 510 between the cubic REO layer 504 and the silicon layer 502. Interface 510 may be an abrupt rotation in crystal orientation between the <100> orientation of the silicon layer 502 and the <110> orientation of the cubic REO layer. This abrupt rotation takes advantage of the energetically favorable growth of <110> cubic REO on <100> silicon, and thus reduces polymorphisms in the cubic REO layer, as well as lattice strain between the silicon layer 502 and the cubic REO layer 504.

The interface 512 may be a second abrupt rotation in crystal orientation between the <110> orientation of the cubic REO layer 504 and the <100> orientation of the RE-V containing layer 506. This abrupt rotation takes advantage of the energetically favorable growth of RE-V <100> on cubic REO in a <110> orientation. Allowing the rotation between the <100> and <110> crystal orientations reduces lattice strain between the RE-V containing layer 506 and the cubic REO layer 504. The abrupt rotation at interface 512 may also reduce polymorphisms in the RE-V containing layer 506, which would affect the quality of the Group III-V semiconductor layer 508.

The interface 512 may also be a graded transition area that minimizes lattice mismatch and reduces dislocation density. This interface is described in further detail with reference to FIG. 11.

The interface 514 between the RE-V containing layer 506 and the Group III-V containing layer 508 may be a graded transition area that minimizes lattice mismatch and reduces dislocation density. This interface is described in further detail with reference to FIG. 11.

The Group V metal in the RE-V containing layer 506 may be the same Group V metal in the Group III-V semiconductor layer 508. Using the same Group V metal through both of these layers reduces exchange reactions and improve the layer structure 500 performance, particularly in photonic devices. The RE-V containing layer 506 may also provide a thermally and energetically stable nucleation for growth of the Group III-V semiconductor layer.

FIG. 6 is a layer diagram of a structure with a Group III-V semiconductor layer having a <100> orientation on Si<100> via a cubic rare earth nitride (REN) layer and a cubic REO layer, according to an illustrative implementation. The layer structure 600 includes a silicon layer 602. The cubic REN layer 604, having a <100> orientation is over the silicon layer 602. A cubic REO layer 606 having a <100> orientation is over both the silicon layer 602 and the cubic REN layer 604. Finally the Group III-V semiconductor layer 608 having a <100> orientation is over the cubic REO layer 606, the cubic REN layer 604, and the silicon layer 602. The silicon layer 602 may be the silicon layer 302, the cubic REO layer 606 may be the REO buffer layer 304, and the Group III-V semiconductor layer 608 may be the Group III semiconductor layer 306, all with reference the FIG. 3. There may be additional layers between silicon layer 602 and cubic REN layer 604 (not shown). There may be additional layers between cubic REN layer 604 and cubic REO layer 606. There may also be additional layers between cubic REO layer 606 and Group III-V semiconductor layer 608 (not shown). The silicon layer 602 may be formed over additional layers (not shown).

As shown in FIG. 6, the crystal orientations of layers 602, 604, 606 and 608 are all in a <100> orientation, thus the layer structure 600 does not contain rotations between crystal orientations. Instead, the addition of the cubic REN layer 604 as well as the cubic REO layer 606 having a <100> orientation reduces the lattice strain between the Group III-V semiconductor layer 608 having a <100> orientation and the silicon layer 602 having a <100> orientation. This allows for a single crystal orientation to be maintained throughout the layer structure 600. The REN layer 604 stabilizes the growth of cubic REO layer 606 in a <100> orientation. Stabilization of the polar <100> orientation of the REO layer 606 may be easier over a REN layer 604 having a <100> orientation than over silicon having a <100> orientation, because the same cation (rare earth metal) may be used in both layer 604 and 606. The continuation of the cation thus produces a higher quality cubic REO layer 606 on which to grow the Group III-V semiconductor layer 608.

The interface 610 between the RE-V containing layer 506 and the Group III-V containing layer 508 may be a graded transition area that minimizes lattice mismatch and reduces dislocation density. This interface is described in further detail with reference to FIG. 11.

The layer structures shown in FIG. 4-6 all include Group III semiconductor layers in a cubic crystal structure. The various intermediate layers between silicon having a <100> orientation and the Group III semiconductor layers reduce lattice strain in layer structures 400, 500 and 600 that result from Group III semiconductor layers over silicon having a <100> orientation.

FIG. 7 is a general layer diagram of a structure with a Group III nitride (III-N) semiconductor layer on Si<100> via a cubic REO layer and a hexagonal REO layer, according to an illustrative implementation. Layer structure 700 shows a Group III-N semiconductor layer 708 formed over a silicon layer 702 having a <100> orientation. The intermediate layers include a cubic REO layer 704 over the silicon layer 702, and a hexagonal REO layer 706 having a <0001> orientation over the cubic REO layer 704 and the silicon layer 702. Group III nitride naturally forms a polar crystal orientation having a hexagonal structure. Hexagonal crystal structure over cubic structures may produce energetically favorable interfaces that allow for growth of Group III nitride in polar crystal orientation on silicon having <100> crystal orientation.

The interface 710 between the silicon layer 702 and the cubic REO layer 704 may be an abrupt rotation in crystal orientation between the <100> orientation of the silicon layer 702 and a <110> orientation of the cubic REO layer 704. The cubic REO layer 704 may be pseudo lattice matched with the hexagonal REO layer 706, meaning that the REO layer 704 may be lattice matched to the hexagonal REO layer 706 along one crystallographic direction, but may be mismatched along a second crystallographic direction. Thus throughout the layer structure 700, the lattice strain between the Group III-N semiconductor layer 708 and the silicon layer 702 is reduced through the interface 710 and the rare earth containing layers 704 and 706.

FIG. 8 is a layer diagram of a structure with a III-N semiconductor layer having a <0001> orientation on Si<100> via a cubic REO layer, a hexagonal REO layer and a cubic REN layer, according to an illustrative implementation. The layer structure 800 shows a Group III-N semiconductor layer 810 having a polar crystal orientation <0001> over a silicon layer 802 having a <100> orientation. The lattice strain between layer 810 and 802 is reduced through the use of intermediate layers 804, 806 and 808. A cubic REO layer 804 having a <110> orientation is over a silicon layer 802 having a <100> orientation. A hexagonal REO layer 806 having a <0001> orientation is over the cubic REO layer 804 and the silicon layer 802. A cubic REN layer 808 having a <111> orientation is over the hexagonal REO layer 806, the cubic REO layer 804 and the silicon layer 802. Finally the Group III-N layer 810 having a <0001> orientation is over the cubic REN layer 808, the hexagonal REO layer 806, the cubic REO layer 804 and the silicon layer 802.

The interface 812 between the silicon layer 802 and the cubic REO layer 804 is an abrupt rotation in crystal orientation between the <100> orientation of the silicon layer 802 and a <110> orientation of the cubic REO layer 804. The interface 814 between the cubic REO layer 804 and the hexagonal REO layer 806 may be a graded transition area that minimizes lattice mismatch and reduces dislocation density. This interface is described in further detail with reference to FIG. 11.

The hexagonal REO layer 806 may be pseudo lattice matched with the cubic REO layer 804, meaning that the cubic REO layer 804 is matched to the hexagonal REO layer 806 along one crystallographic direction, but may be mismatched along a second crystallographic direction. An example of a lattice matched cubic-hexagonal interface may include Sc₂O₃ adjacent to hexagonal La₂O₃ <0001> or hexagonal Nd₂O₃ <0001>. Other examples may include Gd₂O₃ <110> adjacent to hexagonal La2O3 <0001>, hexagonal Nd2O3 <0001>, or hexagonal Pr₂O₃, Dy₂O₃ <110> adjacent to hexagonal La2O3 <0001>, hexagonal Nd2O3 <0001>, or hexagonal Pr2O3, Er₂O₃ <110> adjacent to hexagonal La2O3 <0001>, hexagonal Nd2O3 <0001>, or hexagonal Pr2O3. The cubic REO layer 804 may be lattice matched to the hexagonal REO layer 806 using multiple binary alloys or graded ternary alloys. The rare earth metal may be the same rare earth metal throughout layers 804, 806 and 808.

The cubic REN layer 808 functions to cap the hexagonal REO layer 806, thus improving the chemical stability of the hexagonal REO layer 806. The cubic REN layer may be composed of LaN, ErN, ScN, or any other rare earth nitride that forms a cubic lattice structure in a <111> orientation. The cubic REN layer 806 may also reduce the lattice mismatch for growth of the Group III-N semiconductor layer 810, thus providing a more energetically favorable interface for the layer 810 growth and improving the quality of the Group III-N semiconductor layer 810.

The layer structure 800 may not include the cubic REN layer 808. In this case, layer structure 800 would have a cubic REO layer 804 having a <110> orientation is over a silicon layer 802 having a <100> orientation. A hexagonal REO layer 806 having a <0001> orientation would be over the cubic REO layer 804 and the silicon layer 802. The Group III-N semiconductor layer 810 would then be over the hexagonal REO layer 806, the cubic REO layer 804 and the silicon layer 802. In this case, the removal of the cubic REN layer 808 may reduce the number of steps needed to epitaxially grow layer structure 800. The removal of cubic REN layer 808 may also avoid the difficulty of working with REN material, which is not stable in atmosphere.

The cubic REN layer 808 may also be substituted with a cubic REO layer having a <111> orientation (not shown). In this case, layer structure 800 would have a cubic REO layer 804 having a <110> orientation over a silicon layer 802 having a <100> orientation. A hexagonal REO layer 806 having a <0001> orientation would be over the cubic REO layer 804 and the silicon layer 802. The cubic REO layer <111> would be over the hexagonal REO layer 806, the cubic REO layer 804 and the silicon layer 802. Finally the Group III-N semiconductor layer 810 would be over the cubic REO layer (not shown). The interface between the cubic REO layer having a <111> orientation and the hexagonal REO layer 806 may be an abrupt rotation in crystal orientation between the <111> orientation of the cubic REO layer and the <0001> orientation of the hexagonal REO layer 806. The interface between the cubic REO layer having a <111> orientation and the hexagonal REO layer 806 may also be a graded transition area that minimizes lattice mismatch and reduces dislocation density. This interface is described in further detail with reference to FIG. 11.

FIG. 9 is a layer diagram of a structure with a III-N semiconductor layer having a <0001> orientation on Si<100> via a cubic REO layer, a hexagonal rare earth silicide (RESi) layer, a hexagonal REO layer and a cubic REN layer, according to an illustrative implementation. The layer structure 900 shows Group III-N semiconductor layer 912 having a <0001> orientation over a silicon layer 902 having a <100> orientation. The layers in between semiconductor layer 912 and silicon layer 902 reduce the lattice strain between these two layers. A cubic REO layer 904 having a <110> orientation is over the silicon layer 902. A hexagonal rare earth silicide (RESi) is over the cubic REO layer 904 and the silicon layer 902. A hexagonal REO layer 908 having a <0001> orientation is over the hexagonal RESi layer 906, the cubic REO layer 904 and the silicon layer 902. A cubic REN layer 910 having a <111> orientation is over the hexagonal REO layer 908, the hexagonal RESi layer 906, the cubic REO layer 904 and the silicon layer 902.

The interface 914 may be an abrupt rotation in crystal orientation between the <100> orientation of the silicon layer 902 and a <110> orientation of the cubic REO layer 904. The interface 916 may be an abrupt rotation in crystal orientation between the <110> orientation of the cubic REO layer 904 and the hexagonal RESi layer 906 orientation, which may be in a polar <0001> orientation. The interface 916 improves conductivity of the layer structure 900, since RESi materials are semi-metals with resistivity similar to that of NiSi. Examples of RESi materials that make up layer 906 may include ErSi₁ which has a resistivity of 34×10⁻⁶ Ωcm, GdSi_{1.7} which has a resistivity of 86×10-6 Ωcm, or any other suitable RESi material.

The rare earth metal may be the same in layers 904, 906, 908 and 910, thus further reducing lattice strain and improving the performance of the Group III-N semiconductor layer 912.

The cubic REN layer 910 may also be substituted with a cubic REO layer having a <111> orientation (not shown). In this case, layer structure 900 would include a cubic REO layer 904 having a <110> orientation over the silicon layer 902. A hexagonal rare earth silicide (RESi) would be over the cubic REO layer 904 and the silicon layer 902. A hexagonal REO layer 908 having a <0001> orientation would be over the hexagonal RESi layer 906, the cubic REO layer 904 and the silicon layer 902. A cubic REO layer having a <111> orientation (not shown) would be over the hexagonal REO layer 908, the RESi layer 906, the cubic REO layer 904, and the silicon layer 902. Finally, the Group III-N semiconductor layer 912 would be over the cubic REO layer having a <111> orientation, the hexagonal REO layer 908, the RESi layer 906, the cubic REO layer 904, and the silicon layer 902. The interface between the cubic REO layer having a <111> orientation and the hexagonal REO layer 908 may be an abrupt rotation in crystal orientation between the <111> orientation of the cubic REO layer and the <0001> orientation of the hexagonal REO layer 908. The interface between the cubic REO layer having a <111> orientation and the hexagonal REO layer 908 may also be a graded transition area that minimizes lattice mismatch and reduces dislocation density. This interface is described in further detail with reference to FIG. 11.

FIG. 10 is a layer diagram of a structure with a III-N semiconductor layer having a <0001> orientation on Si<110> via a hexagonal REO layer and a cubic REN layer, according to an illustrative implementation. Layer structure 1000 shows Group III-N semiconductor layer 1008 over silicon layer 1002 having a <110> orientation. The intermediate layers 1004 and 1006 reduce the lattice strain between layer 1008 and 1002. A hexagonal REO layer 1004 having a <0001> orientation is over the silicon layer 1002. A cubic REN layer 1006 having a <111> orientation is over the hexagonal REO layer 1004 and the silicon layer 1002. The Group III-N semiconductor layer 1008 is then over the cubic REN layer 1006, the hexagonal REO layer 1004 and the silicon layer 1002.

The interface between cubic lattice structures in layers 1002 and 1006 and hexagonal lattice structures in layers 1008 and 1004 is described in further detail with reference to FIG. 12.

FIG. 11 is a layer diagram of a chemical barrier between layers formed in subsequent processing, according to an illustrative implementation. As shown in layer structure 1102, adjacent layers 1106 and 1104 may have intermixing and migration of an anion species C 1110 or cation species B 1108. As a result of the growth process of layer 1106 over adjacent layer 1104, an anion species C 1110 may migrate and intermix with the material of adjacent layer 1104. The cation species B 1108 may also migrate and intermix with its adjacent layer 1106. This behavior of both anion 1110 and cation 1108 may be particularly prevalent if adjacent layers 1106 and 1108 share either the same anion or the same cation. The resulting layer structure 1102 has improved interface behavior, which may reduce lattice strain between 1106 and 1108, reduce dislocation density, and improve conductivity across the interface between 1106 and 1108.

As shown in layer structure 1120, the intermixing and migration between adjacent layers 1126 and 1122 may produce a region 1124 that is made up in part by an alloy of a material in layer 1126 and a material of 1122. The material Y may be a cation or an anion. The material X may be a cation or an anion. The alloy region 1124 may be between 50 and 200 nm, and is preferably approximately 100 nm (meaning ±5 nm). The region 1124 at the interface between adjacent layers 1126 and 1122 may reduce lattice strain between layers 1126 and 1122, reduce dislocation density, and improve conductivity across the interface between 1126 and 1122.

In an example, material X in layers 1108 and layers 1122 is a REN material and material Y in layers 1106 and 1126 is a REO material. In this specific example, the REO layers 1106 and 1126 are being used as gate dielectric layers on a REN semiconductor layers 1106 and 1126. The rock-salt structure of REN and the cubic bixbyite structure of most REOs are epitaxially compatible. Minimizing the lattice mismatch a the interface between adjacent layers 1108 and 1106, as well as adjacent layers 1122 and 1126, will help reduce dislocation density in the gate dielectric layers 1106 and 1126 (which is critical because dislocations can serve as fixed charge centers in the dielectric).

FIG. 12 is a schematic diagram of crystallographic alignment for hexagonal material on cubic material, according to an illustrative implementation. As described in layer structures 700, 800, 900 and 1000 (shown in FIGS. 7, 8, 9 and 10 respectively) a layer having a cubic crystal structure in either a <100> or <110> orientation may be adjacent to a layer having a hexagonal crystal structure in a <0001> orientation. The diagram 1200 shows the alignment between the cubic crystal structure 1202 and the hexagonal crystal structure 1204. The orientation of the hexagonal material is shown at 1206, with axes 1208 and 1210. The orientation of the cubic material is shown at 1212, with axes 1214 and 1216 showing the relative orientations between the two materials.

The growth and/or deposition described herein can be performed using one or more of chemical vapor deposition (CVD), metalorganic chemical vapor deposition (MOCVD), organometallic vapor phase epitaxy (OMVPE), atomic layer deposition (ALD), molecular beam epitaxy (MBE), halide vapor phase epitaxy (HVPE), pulsed laser deposition (PLD), and/or physical vapor deposition (PVD).

III-nitride materials are semiconducting materials comprising nitrogen and one or more Group III elements. Common Group III elements used to form III-nitride materials include aluminum, gallium, and indium. III-nitride materials have large direct band gaps, making them useful for high-voltage devices, radio-frequency devices, and optical devices. Furthermore, because multiple Group III elements can be combined in a single III-nitride film in varying compositions, the properties of III-nitride films are highly tunable.

III-V and III-nitride materials can be formed using metal-organic chemical vapor deposition (MOCVD). In MOCVD, one or more Group III precursors react with a Group V precursor to deposit a III-nitride film on a substrate. Some Group III precursors include trimethylgallium (TMGa) as a gallium source, trimethylaluminum (TMA) as an aluminum source, and trimethylindium (TMI) as an indium source. Ammonia is a Group V precursor which can be used as a nitrogen source. Tert-butylarsine and arsine are Group V precursors which can be used as arsenic sources. Tert-butylphosphine and phosphine are Group V precursors which can be used as phosphorous sources.

As described herein, a layer means a substantially-uniform thickness of a material covering a surface. A layer can be either continuous or discontinuous (i.e., having gaps between regions of the material). For example, a layer can completely cover a surface, or be segmented into discrete regions, which collectively define the layer (i.e., regions formed using selective-area epitaxy). A layer structure means a set of layers, and can be a stand-alone structure or part of a larger structure. A III-nitride structure means a structure containing III-nitride material, and can contain additional materials other than III-nitrides, a few examples of which are Si, a silicon oxide (SiOₓ), silicon nitride (SiₓN_{y}) and III-V materials. Likewise, a III-V structure means a structure containing III-V material, and can contain additional materials other than III-Vs, a few examples of which are Si, a silicon oxide (SiOₓ), silicon nitride (SiₓN_{y}) and III-nitride materials (a subset of III-Vs).

“Monolithically-integrated” means formed on the surface of the substrate, typically by depositing layers disposed on the surface.

Disposed on means “exists on” an underlying material or layer. This layer may comprise intermediate layers, such as transitional layers, necessary to ensure a suitable surface. For example, if a material is described to be “disposed on a substrate,” this can mean either (1) the material is in direct contact with the substrate; or (2) the material is in contact with one or more transitional layers that reside on the substrate.

Single-crystal means a crystal structure that comprises substantially only one type of unit-cell. A single-crystal layer, however, may exhibit some crystal defects such as stacking faults, dislocations, or other commonly occurring crystal defects.

Single-domain means a crystalline structure that comprises substantially only one structure of unit-cell and substantially only one orientation of that unit cell. In other words, a single-domain crystal exhibits no twinning or anti-phase domains.

Single-phase means a crystal structure that is both single-crystal and single-domain.

Crystalline means a crystal structure that is substantially single-crystal and substantially single-domain. Crystallinity means the degree to which a crystal structure is single-crystal and single-domain. A highly crystalline structure would be almost entirely, or entirely single-crystal and single-domain.

Epitaxy, epitaxial growth, and epitaxial deposition refer to growth or deposition of a crystalline layer on a crystalline substrate. The crystalline layer is referred to as an epitaxial layer. The crystalline substrate acts as a template and determines the orientation and lattice spacing of the crystalline layer. The crystalline layer can be, in some examples, lattice matched or lattice coincident. A lattice matched crystalline layer can have the same or a very similar lattice spacing as the top surface of the crystalline substrate. A lattice coincident crystalline layer can have a lattice spacing that is an integer multiple, or very similar to an integer multiple, of the lattice spacing of the crystalline substrate. Alternatively, the lattice spacing of the crystalline substrate can be an integer multiple, or very similar to an integer multiple, of the lattice spacing of the lattice coincident crystalline layer. The quality of the epitaxy is based in part on the degree of crystallinity of the crystalline layer. Practically, a high quality epitaxial layer will be a single crystal with minimal defects and few or no grain boundaries.

Substrate means the material on which deposited layers are formed. Exemplary substrates include, without limitation: bulk silicon wafers, in which a wafer comprises a homogeneous thickness of single-crystal silicon; composite wafers, such as a silicon-on-insulator wafer that comprises a layer of silicon that is disposed on a layer of silicon dioxide that is disposed on a bulk silicon handle wafer; or any other material that serves as base layer upon which, or in which, devices are formed. Examples of such other materials that are suitable, as a function of the application, for use as substrate layers and bulk substrates include, without limitation, gallium nitride, silicon carbide, gallium oxide, germanium, alumina, gallium-arsenide, indium-phosphide, silica, silicon dioxide, borosilicate glass, pyrex, and sapphire.

Semiconductor-on-Insulator means a composition that comprises a single-crystal semiconductor layer, a single-phase dielectric layer, and a substrate, wherein the dielectric layer is interposed between the semiconductor layer and the substrate. This structure is reminiscent of prior-art silicon-on-insulator (“SOI”) compositions, which typically include a single-crystal silicon substrate, a non-single-phase dielectric layer (e.g., amorphous silicon dioxide, etc.) and a single-crystal silicon semiconductor layer.

Semiconductor-on-insulator compositions include a dielectric layer that has a single-phase morphology, whereas SOI wafers do not. In fact, the insulator layer of typical SOI wafers is not even single crystal.

Semiconductor-on-insulator compositions include a silicon, germanium, or silicon-germanium “active” layer, whereas prior-art SOI wafers use a silicon active layer. In other words, exemplary semiconductor-on-insulator compositions include, without limitation: silicon-on-insulator, germanium-on-insulator, and silicon-germanium-on-insulator.

The silicon layers described herein may be silicon layers in a semiconductor-on-insulator composition. The silicon layers described herein may be substrate layers. The silicon layers described herein may be incorporated into other layer structures (not shown) in which the silicon layers are over other layers.

A first layer described and/or depicted herein as “on” or “over” a second layer can be immediately adjacent to the second layer, or one or more intervening layers can be between the first and second layers. An intervening layer described and/or depicted as “between” first and second layers can be immediately adjacent to the first and/or the second layers, or one or more additional intervening layers may be between the intervening layer and the first and second layers. A first layer that is described and/or depicted herein as “directly on” or “directly over” a second layer or a substrate is immediately adjacent to the second layer or substrate with no intervening layer present, other than possibly an intervening alloy layer that may form due to mixing of the first layer with the second layer or substrate. In addition, a first layer that is described and/or depicted herein as being “on,” “over,” “directly on,” or “directly over” a second layer or substrate may cover the entire second layer or substrate, or a portion of the second layer or substrate.

A substrate is placed on a substrate holder during layer growth, and so a top surface or an upper surface is the surface of the substrate or layer furthest from the substrate holder, while a bottom surface or a lower surface is the surface of the substrate or layer nearest to the substrate holder. Any of the structures depicted and described herein can be part of larger structures with additional layers above and/or below those depicted. For clarity, the figures herein can omit these additional layers, although these additional layers can be part of the structures disclosed. In addition, the structures depicted can be repeated in units, even if this repetition is not depicted in the figures.

As described herein, the Si<100> and Si<110> single crystal layers are not limited to <100> and <110> silicon, but may also include off cuts with nominal value between 0 and 10° in any direction.

A rare earth oxide (REO) material as described herein may be a material that contains oxygen and one, two, or more rare earth (RE) elements. The rare earth elements as described throughout may include one or more of: lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), luthium (Lu), scandium (Sc) and yttrium (Y), or any other combination thereof.

REOs are known to exhibit fluorite-type structures. These structures exhibit morphology differences as a function of the atomic weight of the rare-earth element present in the oxide, among any other factors.

In particular, oxides comprising lighter rare-earths form cubic CaF₂-type crystal structure as a result of possible ionization states of +2 and/or +3 and/or +4. REOs having this crystal structure exhibit significant net charge defect due to a multiplicity of possible oxidation states. On the other hand, oxides formed from heavier rare-earth elements (e.g., RE₂O₃, etc.), exhibit a distorted CaF₂-type crystal structure known as bixbyite which includes anion vacancies due to an ionization state of RE<3+>. These oxides formed from heavier rare earth elements include Lu₂O₃, Yb₂O₃, Tm₂O₃, Er₂O₃,Ho₂O₃, Dy₂O₃, Tb₂O₃, Gd₂O₃, Sm₂O₃. As described in the present disclosure, an REO may form a tetragonal unit cell, a hexagonal unit cell, or a wurtzite unit cell.

As described herein, Group III-V includes any compounds using a Group III metal with either As, P, or N. A Group III-V may be InP, InGaAs, InGaAsP, InGaAsN, AlN, InGaN, InAlN, GaSb and any other combinations of a Group III metal with As, P or N.

It will be understood that the foregoing is only illustrative of the principles of the disclosure, and that the disclosure can be practiced by other than the described embodiments, which are presented for purposes of illustration and not of limitation, and the present invention is limited only by the claims which follow.

What is claimed is:

1. A layer structure comprising:
a first layer comprising silicon and having a <100> orientation;
a rare earth oxide containing layer over the first layer;
a Group III containing layer over the rare earth oxide containing layer, and having either a <100> orientation or a <0001> orientation; and
wherein the rare earth oxide containing layer and the Group III containing layer are epitaxially formed.

2. The layer structure of claim 1, wherein at least one interface between layers is an abrupt rotation in crystal orientation between a <100> orientation and a <110> orientation.

3. The layer structure of claim 2, wherein the at least one interface is between the first layer and an adjacent layer.

4. The layer structure of claim 2, wherein the at least one interface is between the rare earth oxide containing layer and an adjacent layer.

5. The layer structure of claim 1, wherein at least one interface between a rare earth containing layer and a first adjacent layer has a region with a thickness greater than approximately 100 nm; and
the region comprises an alloy comprising:
a first element of the rare earth containing layer; and
a second element of the adjacent layer.

6. The layer structure of claim 5, wherein:
the first adjacent layer is a Group III-V containing layer; and
the first element is a Group V element.

7. The layer structure of claim 5, wherein:
the first adjacent layer is a crystalline rare earth oxide layer; and
the first element is a rare earth element.

8. The layer structure of claim 1, wherein:
the rare earth oxide containing layer is a crystalline rare earth oxide layer; and
the Group III containing layer is a Group III-V containing layer having a <100> orientation.

9. The layer structure of claim 8, further comprising a nitride layer having a <100> orientation between the first layer and the crystalline rare earth oxide layer.

10. The layer structure of claim 8, further comprising a rare earth and Group V (RE-V) containing layer between the crystalline rare earth oxide layer and the Group III-V containing layer.

11. The layer structure of claim 1, further comprising a hexagonal rare earth oxide layer over the first layer and having a <0001> orientation, and wherein:
the rare earth oxide containing layer is a cubic rare earth oxide layer;
the Group III containing layer is a nitride and Group III (III-nitride) containing layer; and
wherein the hexagonal rare earth oxide layer is epitaxially formed.

12. The layer structure of claim 11, further comprising a cubic rare earth nitride containing layer over the hexagonal rare earth oxide layer.

13. The layer structure of claim 12, wherein an interface between the first layer and the cubic rare earth oxide layer is a single rotation in crystal orientation between a <100> orientation and a <110> orientation.

14. The layer structure of claim 13, further comprising:
a rare earth silicide (RESi) layer having a <0001> orientation; and
wherein:
the RESi layer is adjacent to the cubic rare earth oxide layer, and
an interface between the RESi layer and the cubic rare earth oxide layer is a single rotation in crystal orientation between a <110> orientation and a <0001> orientation.

15. The layer structure of claim 13, wherein an interface between the hexagonal rare earth oxide layer and the cubic rare earth oxide layer is a single rotation in crystal orientation between a <110> orientation and a <0001> orientation.

16. A layer structure comprising:
a first layer comprising silicon and having a <110> orientation;
a hexagonal rare earth oxide layer over the first layer and having a <0001> orientation; and
a III-nitride containing layer over the hexagonal rare earth oxide layer, wherein the hexagonal rare earth oxide layer and the III-nitride containing layer are epitaxially formed, and the III-nitride containing layer has a <0001> orientation.

17. The layer structure of claim 16, further comprising a cubic rare earth nitride (RE-nitride) containing layer having a <111> orientation over the hexagonal rare earth oxide layer.
